(19) United States
(12) Patent Application Publication
(10) Pub. No.: US 2026/0231657 A1
(43) Pub. Date: Aug. 6, 2026

(54) DISPLAY DEVICE AND ELECTRONIC DEVICE HAVING THE SAME

(71) Applicant: Samsung Display Co., LTD., Yongin-si (KR)

(72) Inventors: YONG-HWAN PARK, Yongin-si (KR); SEONGJUN LEE, Yongin-si (KR)

(21) Appl. No.: 19/455,001

(22) Filed: Jan. 21, 2026

(30) Foreign Application Priority Data
Feb. 6, 2025 (KR) 10-2025-0014906

(51) Int. Cl. H10K 59/80; H10K 59/131; H10K 59/38; H10K 59/40

(52) U.S. Cl. CPC H10K 59/8792; H10K 59/131; H10K 59/38; H10K 59/40; H10K 59/873

(57) ABSTRACT

A display device includes a base insulating layer, a lower signal line, an upper signal line, a sensing electrode, at least one inorganic layer, a reflectance-reducing pattern. The sensing electrode is disposed on the base insulating layer covering the lower signal line. The reflectance-reducing pattern including a dye or a pigment is disposed on the at least one inorganic layer. The lower signal line and the upper signal line are connected through at least one contact hole penetrating a corresponding layer among the at least one inorganic layer and the base insulating layer. The upper signal line is covered by the reflectance-reducing pattern.

This application claims priority to Korean Patent Application No. 10-2025- 0014906, filed on February 06, 2025, and all the benefits accruing therefrom under 35 U.S.C. §119, the content of which in its entirety is herein incorporated by reference.

### BACKGROUND

The present disclosure herein relates to a display device and an electronic device having the same, and more particularly, to a display device having an input sensor and an anti-reflection layer, and an electronic device having the same.

Various display devices are being developed for use in multimedia devices such as a television, a mobile phone, a tablet computer, a navigation system, and a game console. Display devices include a keyboard or a mouse as an input device. Additionally, display devices are provided with an input sensor.

### SUMMARY

The present disclosure provides a display device with a reduced defect rate.

The present disclosure also provides an electronic device including a display device.

An embodiment of the invention provides a display device including a base layer including a display region and a non-display region adjacent to the display region, a lower signal line disposed in the non-display region, a base insulating layer covering the lower signal line and overlapping the display region and the non-display region, a light-emitting element disposed on the base insulating layer and overlapping the display region, a thin-film encapsulation layer disposed on the base insulating layer and sealing the light-emitting element, at least one inorganic layer disposed on the thin-film encapsulation layer and overlapping the display region and the non-display region, a sensing electrode disposed on the at least one inorganic layer and overlapping the display region, an upper signal line overlapping the non-display region and connecting the lower signal line and the sensing electrode, a reflectance-reducing pattern disposed on the at least one inorganic layer and including a dye or a pigment, and an overcoat layer disposed on the at least one inorganic layer and overlapping the reflectance-reducing pattern. The lower signal line and the upper signal line are connected through at least one contact hole penetrating a corresponding layer among the at least one inorganic layer and the base insulating layer. The upper signal line is covered by the reflectance-reducing pattern.

In an embodiment, the base insulating layer may include an organic layer, and the base insulating layer may cover a side surface of a pad portion of the lower signal line. An opening exposing an upper surface of the pad portion of the lower signal line may be defined in the base insulating layer.

In an embodiment, the thin-film encapsulation layer, the at least one inorganic layer, and the overcoat layer may not overlap the pad portion.

In an embodiment, the overcoat layer may cover the reflectance-reducing pattern, and an end of the overcoat layer may be closer to the pad portion of the lower signal line than an end of the reflectance-reducing pattern.

In an embodiment, the upper signal line may include a first conductive layer, a second conductive layer disposed on the first conductive layer, and a third conductive layer disposed on the second conductive layer.

In an embodiment, the reflectance-reducing pattern may cover side surfaces of the first conductive layer, the second conductive layer, and the third conductive layers.

In an embodiment, the at least one contact hole may include a first contact hole penetrating the base insulating layer and a second contact hole penetrating the at least one inorganic layer.

In an embodiment, the at least one inorganic layer may be disposed inside the first contact hole, and the second contact hole may be disposed inside the first contact hole.

In an embodiment, the at least inorganic layer may include a first inorganic layer and a second inorganic layer disposed on the first inorganic layer. The sensing electrode may include a first sensing electrode and a second sensing electrode that are insulated from and intersected with each other in a plan view. The first sensing electrode may have an integral shape, and the second sensing electrode may include a sensing pattern disposed at a same layer as the first sensing electrode and a bridge pattern disposed at a layer different from a layer at which the sensing pattern is disposed. The bridge pattern may be disposed between the first inorganic layer and the second inorganic layer and may be connected to the sensing pattern through a contact hole penetrating the second inorganic layer.

In an embodiment, the reflectance-reducing pattern may include a black matrix including a black pigment or a black dye. The black matrix is in contact with the upper signal line and an upper surface of the at least one inorganic layer.

In an embodiment, the reflectance-reducing pattern may be disposed on the at least one inorganic layer and may further include a color filter overlapping the light- emitting element, and the color filter may be disposed on the black matrix.

In an embodiment of the invention, the display device may further include a first color filter, a second color filter, and a third color filter that are disposed on the at least one inorganic layer and have different colors. The light-emitting element may include a first color light-emitting element disposed under the first color filter, a second color light-emitting element disposed under the second color filter, and a third color light-emitting element disposed under the third color filter. The reflectance-reducing pattern may include a same material as any one among the first color filter, the second color filter, and the third color filter.

In an embodiment, one among the first color filter, the second color filter, and the third color filter may be in contact with the sensing electrode. The reflectance- reducing pattern may include a same material as a color filter in contact with the sensing electrode.

In an embodiment, the reflectance-reducing pattern may overlap the sensing electrode, and the upper signal line may have a same stacked structure as the sensing electrode.

In an embodiment of the invention, an electronic device includes a display device including a display region and a non-display region adjacent to the display region, and a circuit board electrically connected to the display device. The display device includes a lower signal line disposed on the non-display region, a base insulating layer covering the lower signal line and overlapping the display region and the non-display region, a light-emitting element disposed on the base insulating layer and overlapping the display region, a thin-film encapsulation layer disposed on the base insulating layer and sealing the light-emitting element, at least one inorganic layer disposed on the thin-film encapsulation layer and overlapping the display region and the non-display region, a sensing electrode disposed on the at least one inorganic layer and overlapping the display region, an upper signal line overlapping the non-display region and connecting the lower signal line and the sensing electrode, a reflectance- reducing pattern disposed on the at least one inorganic layer and including a dye or a pigment, and an overcoat layer disposed on the at least one inorganic layer and overlapping the reflectance-reducing pattern. The lower signal line and the upper signal line are connected through at least one contact hole penetrating a corresponding layer among the at least one inorganic layer and the base insulating layer, and the upper signal line is covered by the reflectance-reducing pattern.

In an embodiment of the invention, an electronic device further may include an anisotropic conductive adhesive layer, and the circuit board may include a substrate signal line, and the substrate signal line and the lower signal line may be electrically connected through the anisotropic conductive adhesive layer. The base insulating layer may include an organic layer, and an opening exposing an upper surface of a pad portion of the lower signal line may be defined in the base insulating layer, and the base insulating layer and the pad portion of the lower signal line may be in contact with the anisotropic conductive adhesive layer.

In an embodiment, the electronic device may not include a polarizing film disposed inside or outside the display device.

In an embodiment, the upper signal line may include a first conductive layer, a second conductive layer disposed on the first conductive layer, and a third conductive layer disposed on the second conductive layer, and the reflectance-reducing pattern may cover side surfaces of the first conductive layer, the second conductive layer, and the third conductive layer.

In an embodiment, the at least one contact hole may include a first contact hole penetrating the base insulating layer and a second contact hole penetrating the at least one inorganic layer. The at least one inorganic layer may be disposed inside the first contact hole, and the second contact hole may be disposed inside the first contact hole.

In an embodiment, the reflectance-reducing pattern may include a black matrix including a black pigment or a black dye. The black matrix may be in contact with the upper signal line and an upper surface of the at least one inorganic layer.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a block diagram of an electronic device according to an embodiment of the invention;

FIG. 2 illustrates schematic views of electronic devices according to embodiments of the invention;

FIGS. 3A and 3B are perspective views of a display device according to an embodiment of the invention;

FIG. 4 is a cross-sectional view of a display device according to an embodiment of the invention;

FIG. 5 is a plan view of a display panel according to an embodiment of the invention;

FIG. 6 is a cross-sectional view of a display device according to an embodiment of the invention;

FIG. 7A is a plan view of an input sensor according to an embodiment of the invention;

FIG. 7B is a first plan view of the input sensor illustrated in FIG. 7A;

FIG. 7C is a second plan view of the input sensor illustrated in FIG. 7A;

FIG. 8A is a cross-sectional view of a display device taken along line I-I' of FIG. 7A;

FIG. 8B is an enlarged cross-sectional view of a portion of FIG. 8A;

FIG. 8C is a cross-sectional view of a display device taken along line II-II' of FIG. 7A;

FIG. 8D is a cross-sectional view of a display device taken along line III-III' of FIG. 7A;

FIG. 9A is a cross-sectional view of a display device taken along line I-I' of FIG. 7A according to another embodiment of the invention; and

FIG. 9B is a cross-sectional view of a display device taken along line II-II' of FIG. 7A according to another embodiment of the invention.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms "first", "second", etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the invention. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms "below", "under", "on the lower side", "above", "over", "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention are described with reference to the accompanying drawings.

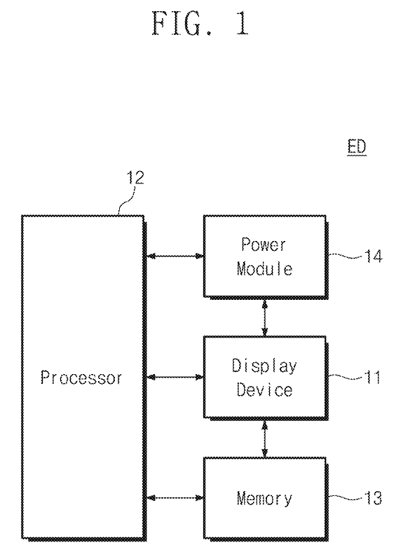

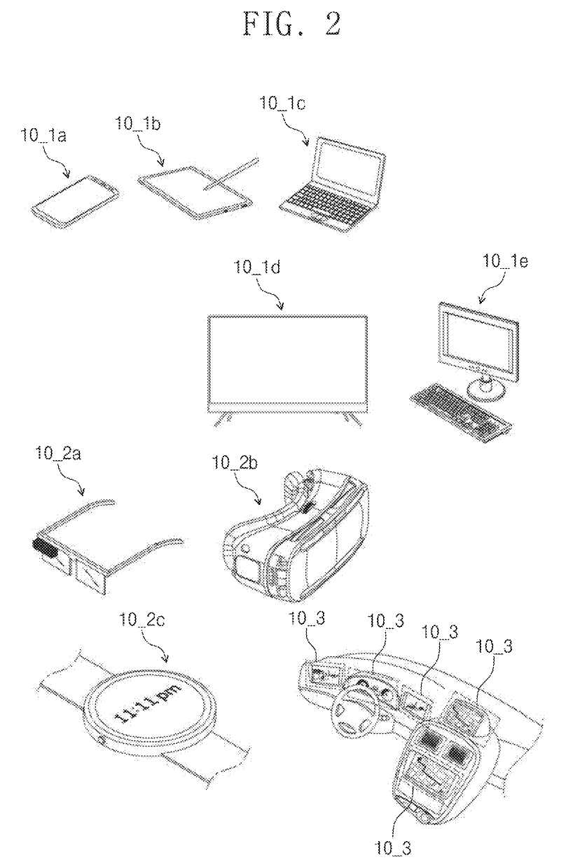

FIG. 1 is a block diagram of an electronic device ED according to an embodiment of the invention. FIG. 2 illustrates schematic views of electronic devices ED according to embodiments of the invention.

Referring to FIG. 1, the electronic device ED according to an embodiment may include a display device 11, a processor 12, a memory 13, and a power module 14.

The processor 12 may include at least one among a central processing unit (CPU), an application processor (AP), a graphic processing unit (GPU), a communication processor (CP), an image signal processor (ISP), and a controller.

The memory 15 may store data information necessary for an operation of the processor 12 or the display device 11. When the processor 12 executes an application stored in the memory 15, an image data signal and/or an input control signal may be transferred to the display module 11, and the display module 11 may process the received signal and output image information through a display screen.

The power module 14 may include a power supply module, such as a power adaptor or a battery device, and a power conversion module that converts power supplied by the power supply module to generate power required for an operation of the electronic device ED.

The processor 12, the power module 14, and the memory 15, which are described above, may be included in the display device 11 or may be provided as individual modules separately from the display device 11. The processor 12, the power module 14, and the memory 15 may be located separately from the display device 11 inside a housing that constitutes the exterior of the electronic device ED.

Referring to FIG. 2, the electronic device ED according to an embodiment of the invention may include not only a typical information-providing electronic device, such as a smart phone 10_la, a tablet PC 10_lb, a laptop 10_ic, a TV 10_id, or a desk monitor 10_le, but also a wearable electronic device, such as smart glasses 10_2a, a head-mounted display device 10_2b, or a smart watch 10_2c, and a vehicular electronic device 103, such as a car dashboard, a center fascia, a center information display (CID) disposed in a dashboard, or a room mirror display.

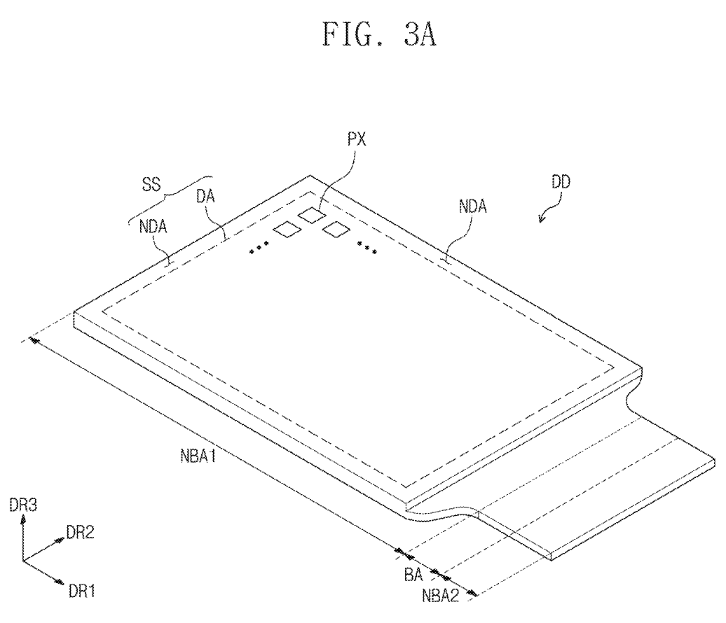

FIGS. 3A and 3B are perspective views of a display device DD according to an embodiment of the invention. The display device DD to be described below may be the display device 11 described with reference to FIGS. 1 and 2.

As illustrated in FIGS. 2A and 1B, a display surface SS on which an image is displayed is parallel to a surface defined by a first direction axis DR1 and a second direction axis DR2. A normal direction of the display surface SS, that is, a thickness direction of the display device DD is indicated by a third direction axis DR3. A front surface (or upper surface) and a rear surface (or lower surface) of each member may be defined based on the third direction axis DR3. Hereinafter, first to third directions are the directions indicated by the first to third direction axes DR1, DR2, and DR3, respectively and are thus denoted as the same reference numerals or symbols.

As illustrated in FIGS. 3A and 3B, the display device DD includes a display region DA on which an image is displayed and a non-display region NDA adjacent to the display region DA. Pixels PX are disposed in the display region DA. The pixels PX may be divided into a plurality of groups according to the colors of light generated or emitted by the pixels PX.

The non-display region NDA is a region on which an image is not displayed. The non-display region NDA may surround the display region DA. However, an embodiment of the invention is not limited thereto, and the shape of the display region DA and the shape of the non-display region NDA may be changed. For example, the non-display region NDA may be disposed adjacent only to a portion of the display region DA.

According to this embodiment, a partial region of the display device DD may be bent. The display device DD may include a first non-bending region NBA1 (or first region), a second non-bending region NBA2 (or third region) spaced apart from the first non-bending region NBA1 in the first direction DR1, and a bending region BA (or second region) defined between the first non-bending region NBA1 and the second non-bending region NBA2. The first non-bending region NBA1 may include the display region DA and a portion of the non-display region NDA. The second non- bending region NBA2 and the bending region BA may all be correspondent to the non- display region NDA, and the second non-bending region NBA2 and the bending region BA may be correspondent to different portions of the non-display region NDA.

The bending region BA may be bent along a bending axis BX. The bending axis BX may be parallel to the second direction DR2. Since the bending region BA is bent, the second non-bending region NBA2 may face the first non-bending region NBA1. The bending region BA and the second non-bending region NBA2 may have a smaller width in the second direction DR2 than the first non-bending region NBA1. FIG. 3A illustrates an unbent status of the display device DD, and FIG. 3B illustrates a bent status of the display device DD in the bending region BA.

The above-described division for the display region DA, the non-display region NDA, the first non-bending region NBA1, the second non-bending region NBA2, and the bending region BA may be similarly applied to each of a display panel DP, an input sensor ISL, and an anti-reflection layer ARL, which are components of the display device DD.

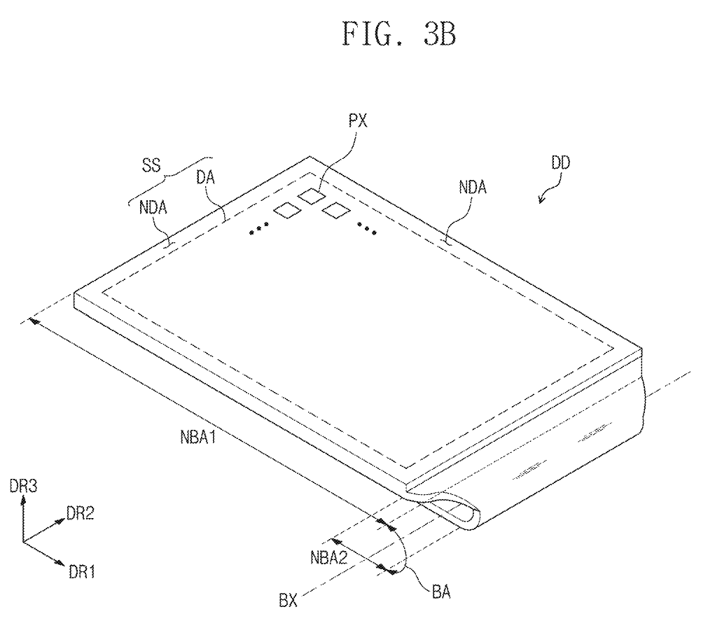

FIG. 4 is a cross-sectional view of a display device DD according to an embodiment of the invention. FIG. 4 illustrates a cross-section defined by the second direction axis DR2 and the third direction axis DR3.

As illustrated in FIG. 4, the display device DD includes the display panel DP, the input sensor ISL, and the anti-reflection layer ARL. Although not separately illustrated, the display device DD according to an embodiment of the invention may further include a protective member disposed on a lower surface of the display panel DP, an anti-reflection member and/or a window member that are disposed on an upper surface of the input sensor ISL.

The display panel DP may be a light-emitting display panel and is not particularly limited. For example, the display panel DP may be an organic light- emitting display panel or inorganic light-emitting display panel. The organic light- emitting display panel has a light-emitting layer that includes an organic light-emitting material. The inorganic light-emitting display panel has a light-emitting layer that includes quantum dots, quantum rods, or a micro-LED. Hereinafter, the display panel DP is described as an organic light-emitting display panel.

The display panel DP may include a base layer BL, a circuit element layer DP- CL, a display element layer DP-EL, and a thin-film encapsulation layer TFE, which are disposed on the base layer BL. The input sensor ISL may be directly disposed on the thin-film encapsulation layer TFE. The anti-reflection layer ARL may be directly disposed on the input sensor ISL. FIG. 4 is a cross-sectional view of a display device DD according to an embodiment of the invention. In this specification, the words, "an A component is directly disposed on a B component" means that an adhesive layer is not disposed between the A component and the B component.

The base layer BL may include a synthetic resin substrate, a glass substrate, a metal substrate, or organic/inorganic composite material substrate, or the like. The display region DA, the non-display region NDA, the first non-bending region NBA1, the second non-bending region NBA2, and the bending region BA, which are described with reference to FIGS. 3A and 3B, may be similarly defined in the base layer BL.

The circuit element layer DP-CL includes at least one insulating layer and a circuit element. The insulating layer includes at least one inorganic layer and at least one organic layer. The circuit element may include a signal line and a pixel circuit. The circuit element layer DP-CL may be formed through a process of forming an insulating layer, a semiconductor layer, and a conductive layer by coating, deposition, and the like, and through a process of patterning the insulating layer, the semiconductor layer, and the conductive layer by a photolithographic process.

The display element layer DP-EL includes a display element. The display element layer DP-EL may further include an organic layer such as a pixel-defining layer. The thin-film encapsulation layer TFE includes a plurality of thin films and seals the display element.

The input sensor ISL may acquire coordination information about an external input. The input sensor ISL may have a multi-layer structure. The input sensor ISL may include a single-layered or multi-layered conductive layer. The input sensor ISL may include a single-layered or multi-layered insulating layer. The input sensor ISL may detect an external input, for example, through an electrostatic capacitance method. In the invention, the operational method of the input sensor ISL is not particularly limited, and in an embodiment of the invention, the input sensor ISL may detect an external input through an electromagnetic induction method or a pressure sensing method.

The anti-reflection layer ARL reduces an external light reflectance. The anti- reflection layer ARL may absorb light incident from the outside. The anti-reflection layer ARL may include an organic layer containing a dye or a pigment.

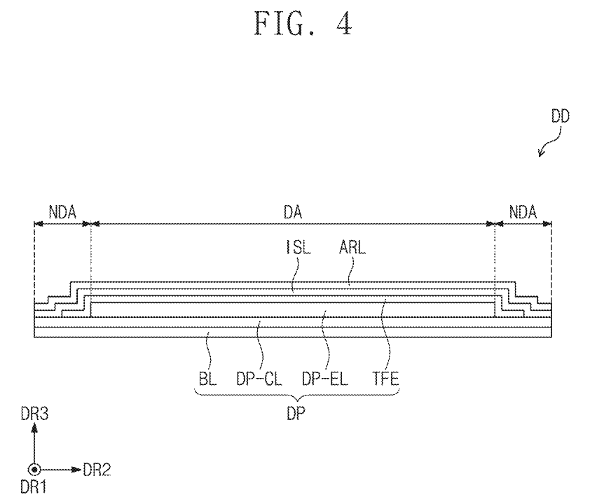

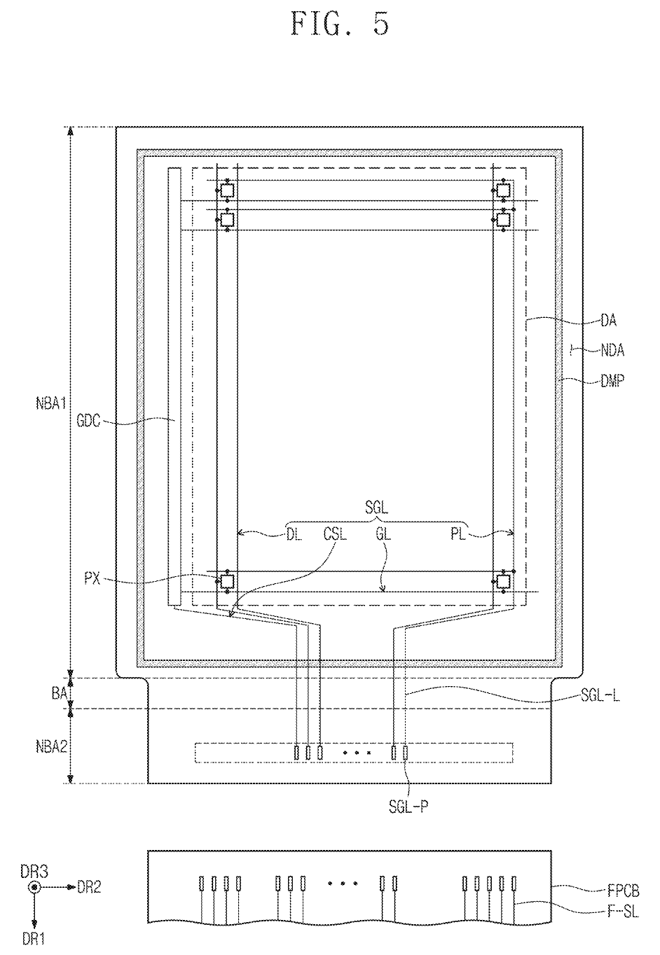

FIG. 5 is a plan view of a display panel DP according to an embodiment of the invention. FIG. 6 is a cross-sectional view of the display device DD according to an embodiment of the invention. As used herein, the "plan view" is a view in a thickness direction (i.e., third direction DR3) of the display device DD.

As illustrated in FIG. 5, the display panel DP may include a driving circuit GDC, a plurality of signal lines SGL, and a plurality of pixels PX. The plurality of pixels PX is disposed in the display region DA. FIG. 5 illustrates an unbent status of the display panel DP.

The driving circuit GDC may include a scan driving circuit. The scan driving circuit GDC generates a plurality of scan signals and sequentially outputs the plurality of scan signals to a plurality of scan lines GL to be described later. The scan driving circuit GDC may further output another control signal to a driving circuit of the pixels PX.

The scan driving circuit GDC may include a plurality of thin-film transistors that are formed through the same process as the driving circuit of the pixels PX, for example, a low temperature polycrystalline silicon (LTPS) process or a low temperature polycrystalline oxide (LTPO) process.

The plurality of signal lines SGL includes the scan lines GL, data lines DL, a power line PL, and a control signal line CSL. Each of the scan lines GL is connected to a corresponding pixel among the plurality of pixels PX, and each of the data lines DL is connected to a corresponding pixel among the plurality of pixels PX. The power line PL is connected to the plurality of pixels PX. The control signal line CSL may provide control signals to the scan driving circuit GDC.

The signal lines SGL include line portions SGL-L and pad portions SGL-P disposed at ends of the line portions SGL-L. The line portions SGL-L may be disposed at the same layer and may have an integral shape. One of the line portions SGL-L and another one of the line portions SGL-L may be disposed on different insulating layers and each may have an integral shape. The line portions SGL-L may also include a plurality of portions disposed on different layers. For example, one line portion SGL- L may include three portions disposed on different layers. Two portions connected to each other among the three portions may be disposed on different layers and may be connected to each other through a contact hole penetrating an insulating layer disposed therebetween.

The pad portions SGL-P may be electrically connected to signal lines F-SL of a circuit board FPCB, respectively. The pad portions SGL-P and the signal lines F-SL may be electrically connected through an anisotropic conductive adhesive layer ACF. The signal lines F-SL may be referred to as "substrate signal lines".

The display panel DP may include an insulating pattern DMP. The insulating pattern DMP is disposed in the non-display region NDA and surrounds the display region DA. The insulating pattern DMP may have a closed line shape. The insulating pattern DMP serves as a dam to prevent a liquid organic material from overflowing during an inkjet process of the display panel DP.

FIG. 6 illustrates a cross-section corresponding to the pixel PX of FIG. 5. FIG. 6 illustrates mainly a light-emitting element LD that is a display element. Additionally, FIG. 6 illustrates, as an example, a transistor TFT of the pixel circuit and a signal line SCL that are disposed in the circuit element layer DP-CL.

A buffer layer BFL may be disposed on the base layer BL. The buffer layer BFL may include a plurality of inorganic layers. A semiconductor pattern SC is disposed on the buffer layer BFL. The buffer layer BFL enhances a bonding strength between the base layer BL and the semiconductor pattern SC.

The semiconductor pattern SC may include polysilicon. However, the semiconductor pattern SC is not limited thereto and may also include amorphous silicon or metal oxide. FIG. 6 illustrates only a portion of the semiconductor pattern SC, and the semiconductor pattern SC may be arranged for each pixel in accordance with a specific rule.

The semiconductor pattern SC has a different electrical property according to whether to be doped or not. The semiconductor pattern SC may include a first region AC1 having a low doping concentration and a low conductivity, and second regions SE1 and DEl having a relatively high doping concentration and a relatively high conductivity. One second region SE1 may be disposed at one side of the first region AC1, and the other second region DEl may be disposed at the other side of the first region AC1. The second regions SE1 and DE1 may be doped with an N-type dopant or a P-type dopant. A P-type transistor includes a doped region which is doped with the P-type dopant. The first region ACl may be an undoped region or may be doped at a lower concentration than the second regions SE1 and DE 1.

The second regions SE1 and DEl substantially serve as electrodes or signal lines. One second region SE1 may correspond to a source of a transistor, and the other second region DEl may correspond to a drain of the transistor. FIG. 6 illustrates the signal line SCL formed from the semiconductor pattern SC. The signal line SCL may be a semiconductor pattern having a high doping concentration and a high conductivity and may include the same material as the second regions SE1 and DEl described above. The signal line SCL may connect different circuit elements. The signal line SCL may be connected to the transistor TFT.

A first insulating layer 10 is disposed on the buffer layer BFL. The first insulating layer 10 entirely overlaps at least the display region DA (see FIG. 3A) and covers the semiconductor pattern SC. The first insulating layer 10 may also be disposed in the non-display region NDA (see FIG. 3A). The first insulating layer 10 may be an inorganic layer and have a single-layer or multi-layer structure. The first insulating layer 10 may include at least one among aluminum oxide, titanium oxide, silicon oxide, silicon nitride, silicon oxynitride, zirconium oxide, and hafnium oxide. Not only the first insulating layer 10 but also second to fourth insulating layers 20 to 40 to be described later may be an inorganic layer and are not limited thereto, and at least one of the first to fourth insulating layers 10 to 40 may be changed to an organic layer.

A gate GT1 is disposed on the first insulating layer 10. The gate GT1 may include a multi-layered metal layer. The gate GT1 overlaps the first region AC1. In a doping process of the semiconductor pattern SC, the gate GT1 serves as a mask for blocking a dopant.

The second insulating layer 20 which covers the gate GT1 is disposed on the first insulating layer 10. The second insulating layer 20 entirely overlaps at least the display region DA (see FIG. 3A) and may also be disposed in the non-display region NDA (see FIG. 3A). An upper electrode UE may be disposed on the second insulating layer 20. The upper electrode ULE may overlap the gate GT1. The upper electrode UE may include a multi-layered metal layer. In embodiment of the invention, the upper electrode UE may also be omitted.

A third insulating layer 30 which covers the upper electrode UE is disposed on the second insulating layer 20. A first connection electrode CNE1 may be disposed on the third insulating layer 30. The first connection electrode CNE1 may be connected to the signal line SCL through a contact hole CNT-1 penetrating the first to third insulating layers 10 to 30.

A fourth insulating layer 40 is disposed on the third insulating layer 30. A fifth insulating layer 50 is disposed on the fourth insulating layer 40. The fifth insulating layer 50 may be an organic layer that provides a flat surface. A second connection electrode CNE2 may be disposed on the fifth insulating layer 50. The second connection electrode CNE2 may be connected to the first connection electrode CNE1 through a contact hole CNT-2 penetrating the fourth insulating layer 40 and the fifth insulating layer 50.

A sixth insulating layer 60 which covers the second connection electrodeCNE2 is disposed on the fifth insulating layer 50. The sixth insulating layer 60 may be an organic layer. An organic light-emitting diode that is the light-emitting element LD is disposed on the sixth insulating layer 60.

A first electrode AE (or anode) is disposed on the sixth insulating layer 60. The first electrode AE is connected to the second connection electrode CNE2 through a contact hole CNT-3 penetrating the sixth insulating layer 60. An opening PDL-OP is defined in a pixel-defining layer PDL. The opening PDL-OP of the pixel-defining layer PDL exposes at least a portion of the first electrode AE. The pixel-defining layer PDL may be an organic layer.

As illustrated in FIG. 6, the display region DA may include a light-emitting region LA and a non-light-emitting region NLA adjacent to the light-emitting region LA. The non-light-emitting region NLA may surround the light-emitting region LA. In this embodiment, the light-emitting region LA is defined to correspond to a partial region of the first electrode AE exposed by the opening PDL-OP.

A hole control layer HCL may be disposed in common in the light-emitting region LA and the non-light-emitting region NLA. The hole control layer HCL may include a hole transport layer and further include a hole injection layer. A light- emitting layer EML is disposed on the hole control layer HCL. The emitting layer EML is disposed at least inside the opening PDL-OP. The light-emitting layer EML may also partially overlap the pixel-defining layer PDL. The light-emitting layer EML may be separately disposed in each of the pixels PX (see FIG. 3A).

An electron control layer ECL is disposed on the light-emitting layer EML. The electron control layer ECL may include an electron transport layer and further include an electron injection layer. The hole control layer HCL and the electron control layer ECL may be formed in common in the plurality of pixels PX (see FIG. 3A ) using an open mask. A second electrode CE (or cathode) is disposed on the electron control layer ECL. The second electrode CE has an integral shape and is disposed in common in the plurality of pixels PX (see FIG. 3A). As illustrated in FIG. 6, the thin-film encapsulation layer TFE is disposed on the second electrode CE.

The thin-film encapsulation layer TFE may include a first inorganic layer IOL1, an organic layer OL, and a second inorganic layer IOL2. The first inorganic layer IOL1 and the second inorganic layer IOL2 may protect the display element layer DP- EL from moisture/oxygen, and the organic layer OL may make the first inorganic layer IOL1 and the second inorganic layer IOL2 spaced apart so as to separate pin holes formed in the first inorganic layer IOL1 and pin holes formed in the second inorganic layer IOL2. Therefore, movements of moisture/oxygen through the pin holes may be reduced.

As illustrated in FIG. 6, the input sensor ISL may include at least one inorganic layer and at least one conductive layer that are disposed on the thin-film encapsulation layer TFE. At least one inorganic layer and at least one conductive layer may overlap the display region DA and the non-display region NDA in FIG. 3A.

According to this embodiment, the input sensor layer ISL may include a first sensor insulating layer 210 (hereinafter, "first insulating layer"), a first sensor conductive layer 220 (hereinafter, "first conductive layer"), a second sensor insulating layer 230 (hereinafter, "second insulating layer"), and a second sensor conductive layer 240 (hereinafter, "second conductive layer"). The first insulating layer 210 may be directly disposed on the thin-film encapsulation layer TFE. The first conductive layer 220 is disposed on the first insulating layer 210. The second insulating layer 230 which covers the first conductive layer 220 is disposed on the first insulating layer 210. The second conductive layer 240 is disposed on the second insulating layer 230.

Each of the first conductive layer 220 and the second conductive layer 240 may include a plurality of conductive patterns. The conductive pattern of the second conductive layer 240 may be connected to the conductive pattern of the first conductive layer 220 through a contact hole 230-CNT penetrating the second insulating layer 230.

Each of the first conductive layer 220 and the second conductive layer 240 may have a single-layer structure or a multi-layer structure stacked along the third direction axis DR3. The conductive pattern of the multi-layer structure may include at least two layers among transparent conductive layers and metal layers. The conductive pattern of the multi-layer structure may include metal layers containing different metals. In this embodiment, each of the first conductive layer 220 and the second conductive layer 240 may include a titanium layer, an aluminum layer, and a titanium layer that are sequentially stacked.

Each of the first insulating layer 210 and the second insulating layer 230 may entirely overlap the display region DA (see FIG. 3A) and may also be disposed in the non-display region NDA (see FIG. 3A). Each of the first insulating layer 210 and the second insulating layer 230 may be an inorganic layer, and include, for example, silicon nitride, silicon oxide, or silicon oxynitride. In an embodiment of the invention, the first insulating layer 210 may be omitted. In an embodiment of the invention, either of the first insulating layer 210 or the second insulating layer 230 may be omitted.

The anti-reflection layer ARL disposed on the input sensor ISL may include a reflectance-reducing pattern. The reflectance-reducing pattern absorbs light incident from the outside and accordingly, prevents or reduces external light from being provided to the conductive patterns disposed therebelow.

The reflectance-reducing pattern includes a material capable of absorbing light and includes, for example, a dye or a pigment. The reflectance- reducing pattern may have different colors according to the color of a dye or pigment. The reflectance-reducing pattern according to this embodiment may replace a polarizing film. Typically, the polarizing film includes a polyvinyl alcohol film and iodine and/or a dichroic dye that are/is disposed on one surface of the polyvinyl alcohol film. The iodine and/or dichroic dye are/is arranged in a stretching direction of a stretched polyvinyl alcohol film. The polarizing film increases a thickness of the display device and increases a manufacturing cost of the display device. The display device according to this embodiment may not include the polarizing film, and the electronic device according to this embodiment may not include the polarizing film disposed inside or outside the display device.

The reflectance-reducing pattern may include a black matrix 310. The black matrix 310 may include a black dye or a black pigment. However, the black matrix 310 is not limited thereto and may also include metal such as chromium, or oxide thereof or carbon black in another embodiment.

The black matrix 310 may cover the conductive pattern of the second conductive layer 240. The black matrix 310 may cover a side surface and an upper surface of the conductive pattern. The black matrix 310 may be in contact with the second insulating layer 230. An opening 310-OP corresponding the light-emitting region LA is defined in the black matrix 310. The opening 310-OP may have a larger area than the light-emitting region LA in a plan view, and the light-emitting region LA may be disposed inside the opening 310-OP.

The reflectance-reducing pattern may include a color filter 320. The color filter 320 may include a dye or a pigment that has a predetermined color. The color filter 320 may include a first color filter, a second color filter, and a third color filter. The first color may be red, the second color may be green, and the third color may be blue.

The color of the color filter 320 may be determined by the light generated from the light-emitting element LD. When a first color light is generated from the light-emitting element LD, the color filter 320 may have a first color to pass the first color light therethrough. Referring to FIG. 5, the pixels include a first pixel containing a first color light-emitting element, a second pixel containing a second color light-emitting element, and a third pixel containing a third color light-emitting element. The color filter 320 may include the first color filter disposed on the first color light- emitting element, the second color filter disposed on the second color light-emitting element, and the third color filter disposed on the third color light-emitting element.

The anti-reflection layer ARL includes an overcoat layer 330 which covers the color filter 320. The overcoat layer 330 may provide a flat upper surface. The overcoat layer 330 may include an organic layer.

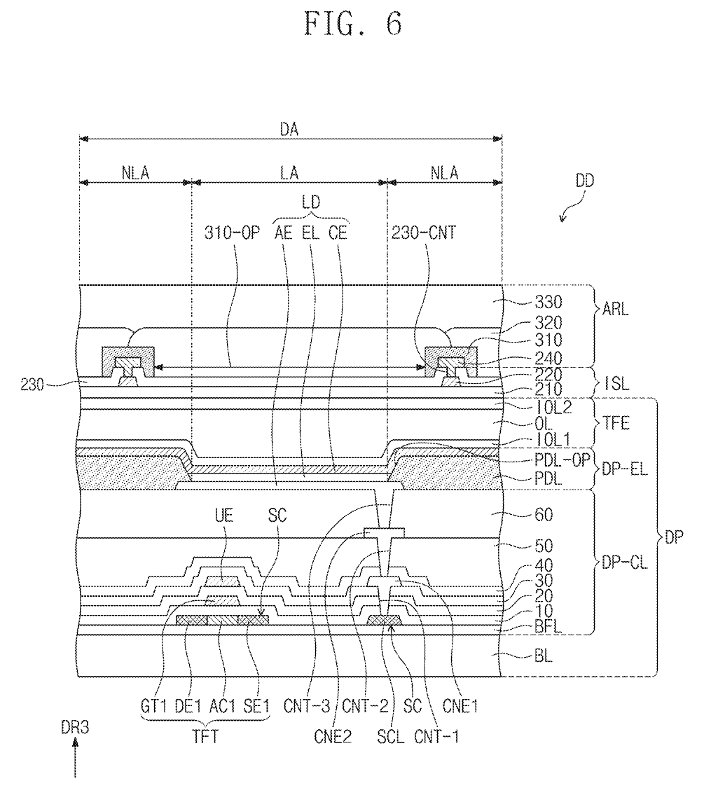

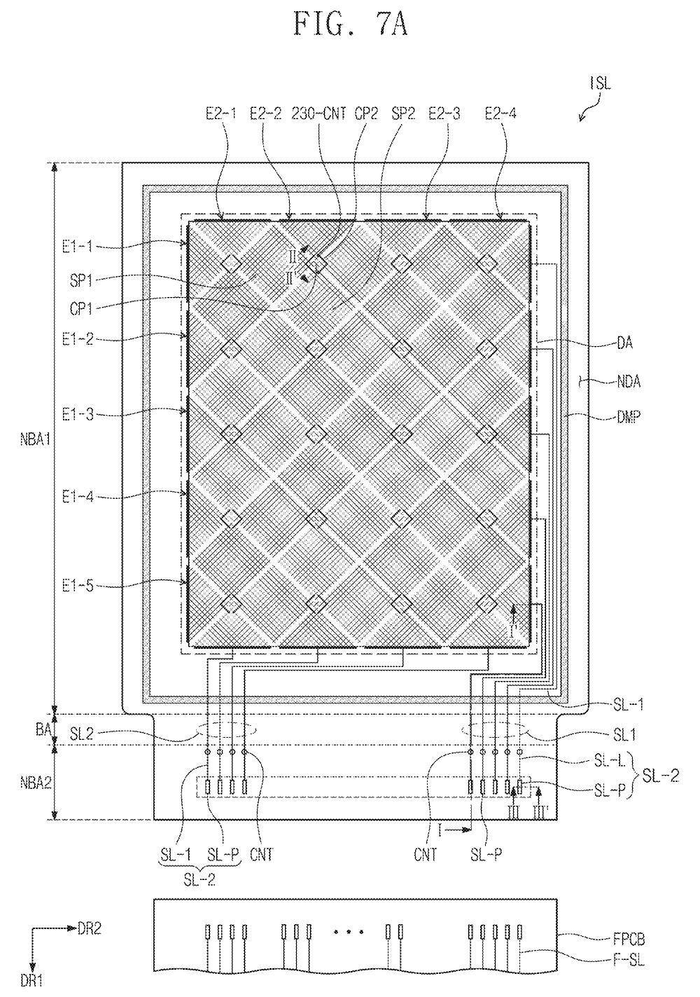

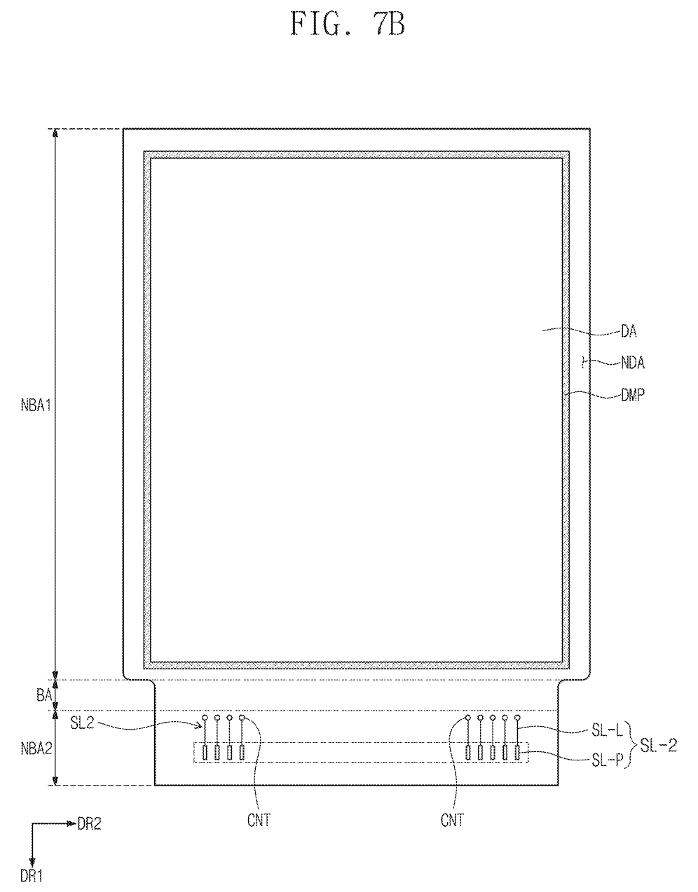

FIG. 7A is a plan view of the input sensor ISL according to an embodiment of the invention. FIG. 7B is a first plan view of the input sensor ISL according to an embodiment of the invention. FIG. 7C is a second plan view of the input sensor ISL according to an embodiment of the invention.

As illustrated in FIG. 7A, the input sensor ISL overlaps the display region DA and the non-display region NDA. The input sensor ISL includes first sensing electrodes El-1 to E1-5 and second sensing electrodes E2-1 to E2-4 that overlap the display region DA and are insulated from and intersected with each other in a plan view.

The first sensing electrodes El-1 to El-5 and the second sensing electrodes E2-1 to E2-4 each have a mesh shape in which a plurality of openings is defined. The plurality of openings is defined to correspond to the light-emitting region LA (see FIG. 6) of the display panel DP. The second sensing electrodes E2-1 to E2-4 are insulated from and intersected with the first sensing electrodes El-1 to El-5 in a plan view. Either of the first sensing electrodes El-1 to El-5 or the second sensing electrodes E2-1 to E2-4 may have an integral shape. In this embodiment, the first sensing electrodes El-1 to El-5 having an integral shape are illustrated as an example. The first sensing electrodes El-1 to El-5 may include sensing portions SP1 and intermediate portions CPl.

Each of the second sensing electrodes E2-1 to E2-4 may include sensing patterns SP2 and bridge patterns CP2 (or connection patterns). Two sensing patterns SP2 adjacent to each other may be connected through two bridge patterns CP2. However, the number of bridge patterns is not limited. The bridge patterns CP2 are included in the first conductive layer 220 illustrated in FIG. 6, and the plurality of first sensing electrodes El-1 to El -5 and the sensing patterns SP2 are included in the second conductive layer 240.

The input sensor ISL overlaps the non-display region NDA and includes first signal lines SL1 connected to the first sensing electrodes El-1 to El-5 and second signal lines SL2 electrically connected to the second sensing electrodes E2-1 to E2-4. Among the first signal lines SL1 and the second signal lines SL2, one signal line transfers, to corresponding electrodes, a transmission signal for sensing an external input from an external circuit, and another signal line transfers, to the external circuit, an electrostatic capacitance change between the first sensing electrodes El-1 to El-5 and the second sensing electrodes E2-1 to E2-4 as a reception signal.

The first signal lines SL1 and the second signal lines SL2 may each include a plurality of portions that are distinct from each other. The first signal lines SL1 and the second signal lines SL2 may respectively include upper signal lines SL-1 and lower signal lines SL-2 that are disposed on different layers. The upper signal line SL-1 and the lower signal line SL-2 are connected to each other through a contact hole CNT penetrating an insulating layer disposed therebetween. Additionally, hereinafter, unless otherwise specified, when an A component and a B component are disposed at the same layer, they are described as being formed through the same process and having the same stacked structure. Additionally, hereinafter, unless otherwise specified, when the A component and the B component are disposed on different layers, they are described as being formed through different processes and having different stacked structures.

The lower signal lines SL-2 illustrated in FIGS. 7A and 7B may include line portions SL-L and pad portions SL-P. The pad portions SL-P of the lower signal lines SL-2 may be electrically connected to the signal lines F-SL of the circuit board FPCB, respectively. The lower signal line SL-2 may be disposed at the same layer as the signal lines SGL described with reference to FIG. 5. Although, in FIG. 5, each of the signal lines SGL is illustrated as a single line, this does not limit the shape of the signal lines SGL. For example, the signal lines SGL may also include a plurality of portions disposed on different layers. Accordingly, the lower signal line SL-2 may be disposed at the same layer as the portions of the signal lines SGL that are disposed in the second non-bending region NBA2 in FIG. 5.

The lower signal line SL-2 may be disposed at the same layer as one of the conductive layers illustrated in FIG. 6. For example, the lower signal lines SL-2 may be disposed at the same layer as one among the gate GT1, the upper electrode UE, the first connection electrode CNE1, and the second connection electrode CNE2.

The upper signal line SL-1 illustrated in FIGS. 7A and 7B may have an integral shape. The upper signal line SL-1 may be disposed at the same layer as the first sensing electrodes El-1 to El-5 and the second sensing electrodes E2-1 to E2-4. The upper signal line SL-1 may be disposed at the same layer as the first conductive layer 220 illustrated in FIG. 6 or may be disposed at the same layer as the second conductive layer 240 illustrated in FIG. 6.

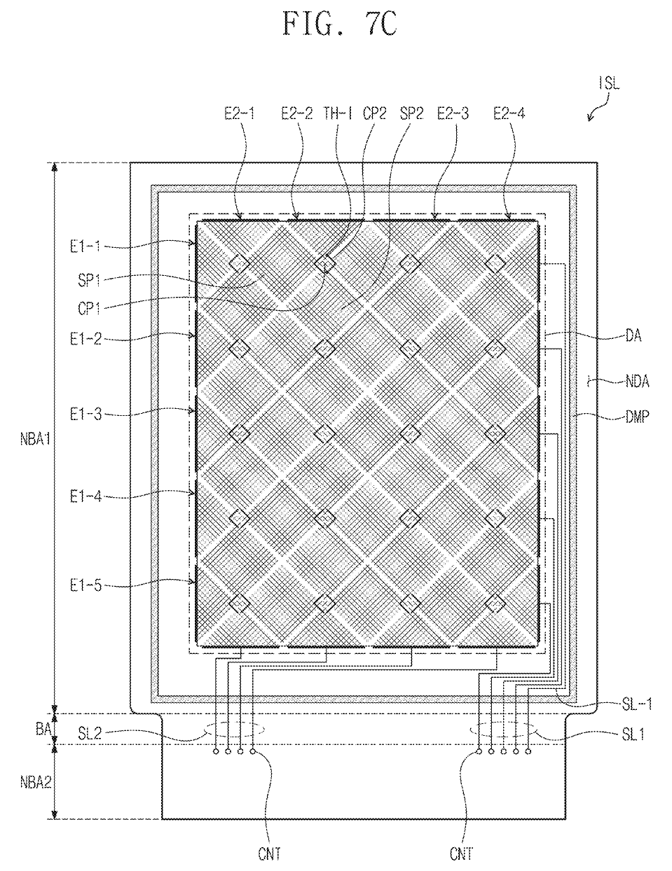

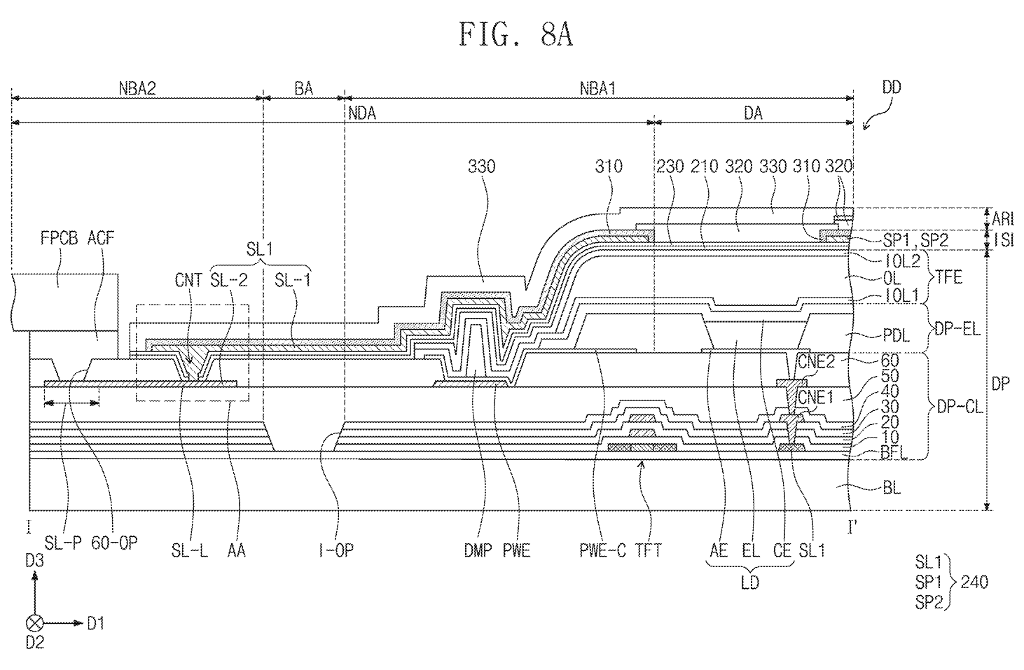

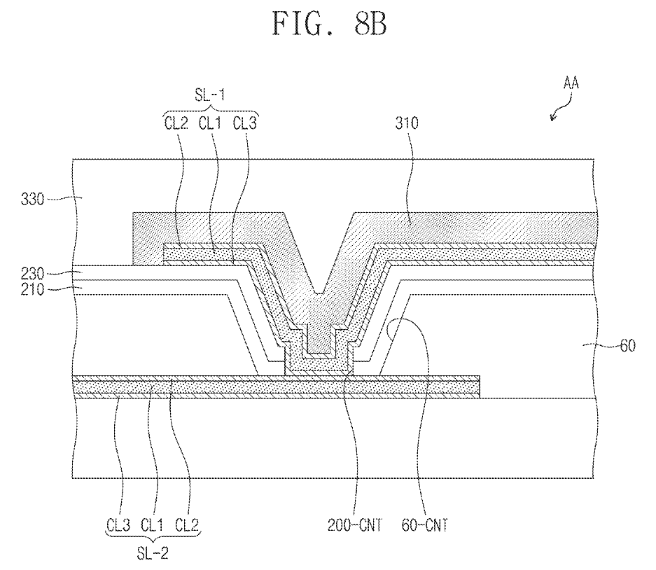

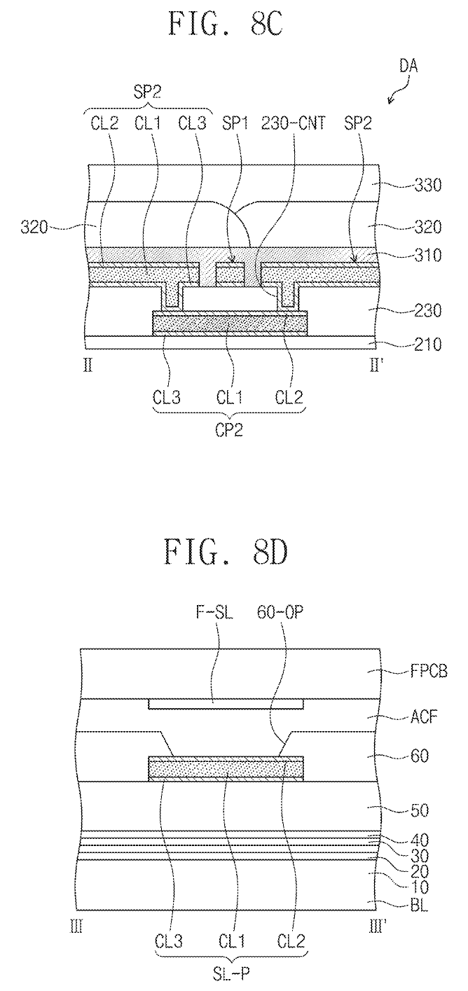

FIG. 8A is a cross-sectional view of the display device DD taken along line I-I' of FIG. 7A in an unbent status. FIG. 8B is an enlarged cross-sectional view of a portion AA of FIG. 8A. FIG. 8C is a cross-sectional view of the display device DD taken along line II-II' of FIG. 7A. FIG. 8D is a cross-sectional view of the display device DD taken along line III-III' of FIG. 7A. In FIG. 8C, components under the first insulating layer 210 are not illustrated.

A stacked structure of the circuit element layer DP-CL, the display element layer DP-EL, and the thin-film encapsulation layer TFE, which are disposed in the display region DA, is the same as the structure of the configuration described with reference to FIG. 6, and the detailed description thereof is referred to the description made with reference to FIG. 6.

As illustrated in FIG. 8A, a power electrode PWE providing a power voltage ELVSS may be disposed in the non-display region NDA of the first non- bending region NBA1. The power electrode PWE may be disposed on the fifth insulating layer 50 and may be formed through the same process as the process for the second connection electrode CNE2. A power connection electrode PWE-C is disposed on the sixth insulating layer 60. The power connection electrode PWE-C connects the power electrode PWE and the second electrode CE. The power connection electrode PWE-C and the first electrode AE may be formed through the same process.

The insulating pattern DMP may overlap the power electrode PWE. The insulating pattern DMP and the pixel-defining layer PDL may be formed through the same process. The organic layer OL of the thin-film encapsulation layer TFE is disposed inside the insulating pattern DMP.

An opening I-OP of the first to fourth insulating layers 10 to 40 is defined in the bending region BA. Unlike what is illustrated in FIG. 8A, the opening I-OP may also extend up to the buffer layer BFL. After the first to fourth insulating layers 10 to 40 are stacked, the opening I-OP may be formed through an etching process. A portion of the fifth insulating layer 50 is disposed inside the opening I-OP.

The lower signal line SL-2 may be disposed on the fifth insulating layer 50. The lower signal line SL-2 and the second connection electrode CNE2 may be formed through the same process. The lower signal line SL-2 may be covered by the sixth insulating layer 60. The sixth insulating layer 60, which covers the lower signal line SL-2 and supports the first electrode AE, may be defined as a base insulating layer.

As illustrated in FIGS. 8A and 8D, the pad portion SL-P of the lower signal line SL-2 may be exposed from the sixth insulating layer 60. An opening 60- OP exposing the pad portion SL-P is defined in the sixth insulating layer 60. An anisotropic conductive adhesive layer ACF, which is in contact with the pad portion SL-P through the opening 60-OP, may electrically connect the pad portion SL-P to the circuit board FPCB.

As illustrated in FIG. 8C, a bridge pattern CP2 may be disposed on the first insulating layer 210 within the display region DA. The first sensing portion SP1 may be disposed on the second insulating layer 230, and the sensing patterns SP2 may be disposed on the second insulating layer 230. Each of the sensing patterns SP2 is connected to the bridge pattern CP2 through the contact hole 230-CNT penetrating the second insulating layer 230.

Referring to FIGS. 8A and 8B, the upper signal line SL-1 may be disposed on the second insulating layer 230. The upper signal lines SL-1 may extend from the display region DA to the non-display region NDA. The upper signal line SL- 1 may be connected to the lower signal line SL-2 through at least one contact hole CNT. The contact hole CNT may be disposed in the second non-bending region NBA2.The upper signal line SL-1 may be formed through the same process as the process for the first sensing portion SP1 and the sensing patterns SP2 illustrated in FIG. 8C.

Referring to FIGS. 8A to 8C, the upper signal line SL-1, the sensing portion SP1, and the sensing pattern SP2 may be covered by the black matrix 310. Referring to FIGS. 8A and 8D, the first insulating layer 210, the second insulating layer 230, the black matrix 310, and the overcoat layer 330 do not overlap the pad portion SL-P in the unbent status.

Referring to FIG. 8A, the overcoat layer 330 may cover the black matrix 310 and surround an end of the black matrix 310. An end of the overcoat layer 330 may face the end of the black matrix 310 and may be disposed closer to the pad portion SL-P than the end of the black matrix 310.

The end of the first insulating layer 210 and the end of the second insulating layer 230 may each be aligned with the end of the overcoat layer 330. The first insulating layer 210 and the second insulating layer 230, which have protected the pad portion SL-P during a manufacturing process of the display device DD, may be dry-etched using the overcoat layer 330 as a mask after the overcoat layer 330 is patterned. Accordingly, the first insulating layer 210 and the second insulating layer 230, which do not overlap the overcoat layer 330, may be removed. As a result, the thin-film encapsulation layer TFE, the first insulating layer 210, the second insulating layer 230, and the overcoat layer 330 may not overlap the pad portion SL-P, and the pad portion SL-P may be exposed from the insulating layers of the display device DD.

Referring to FIGS. 8B to 8D, the upper signal line SL-1 and the lower signal line SL-2 may each have a multi-layer structure. The upper signal line SL-1 and the lower signal line SL-2 may each include a first conductive layer CL1 having a relatively high conductivity, a second conductive layer CL2 disposed on the first conductive layer CL1, and a third conductive layer CL3 disposed under the first conductive layer CL1. The third conductive layer CL3 may have higher bonding strength than the insulating layers disposed under the first conductive layer CL1, and the second conductive layer CL2 may have a smaller reflectance for the external light than the first conductive layer CL1. The second conductive layer CL2 and the third conductive layer CL3 may include the same material. The first conductive layer CL1 may include aluminum, and the second conductive layer CL2 and the third conductive layer CL3 may include titanium.

Referring to FIG. 8B, a contact hole 60-CNT exposing a portion of the lower signal line SL-2 is defined in the sixth insulating layer 60. The contact hole 60- CNT has a relatively large area. Each of the first insulating layer 210 and the second insulating layer 230 may be disposed inside the contact hole 60-CNT. A contact hole 200-CNT penetrating the first insulating layer 210 and the second insulating layer 230 is defined in the first insulating layer 210 and the second insulating layer 230. The contact hole 200-CNT of the first insulating layer 210 and the second insulating layer 230 is disposed inside the contact hole 60-CNT of the sixth insulating layer 60. When the contact hole 60-CNT is defined as a "first contact hole", the contact hole 200-CNT may be defined as a "second contact hole".

Referring to FIGS. 8A and 8D, the forming process of the color filter 320 includes an ashing process in which the color filter is partially removed. The aluminum layer exposed to an ashing liquid is more etched than the titanium layers, and thus does not support the titanium layer. A portion of the titanium layer that is not supported by the aluminum layer may be divided into pieces, thereby causing a short circuit defect between the plurality of pad portions SL-P in FIG. 7A.

According to this embodiment, it is possible to suppress the damage to the lower signal line SL-2 and the upper signal line SL-1 caused by the ashing liquid used in the ashing process. The aluminum layer of the lower signal line SL-2 and the aluminum layer of the upper signal line SL-1 are sealed by a structure so as to prevent the ashing liquid from coming into contact therewith. As illustrated in 8A, a side surface of the lower signal line SL-2 is sealed by the sixth insulating layer 60, and as illustrated in 8B, a side surface of the upper signal line SL-1, specifically, side surfaces of the first conductive layer CL1, the second conductive layer CL2, and the third conductive layer CL3 are covered (or sealed) by the black matrix 310. That is, the lower signal line SL-2 and the upper signal line SL-1 may be protected from the ashing liquid.

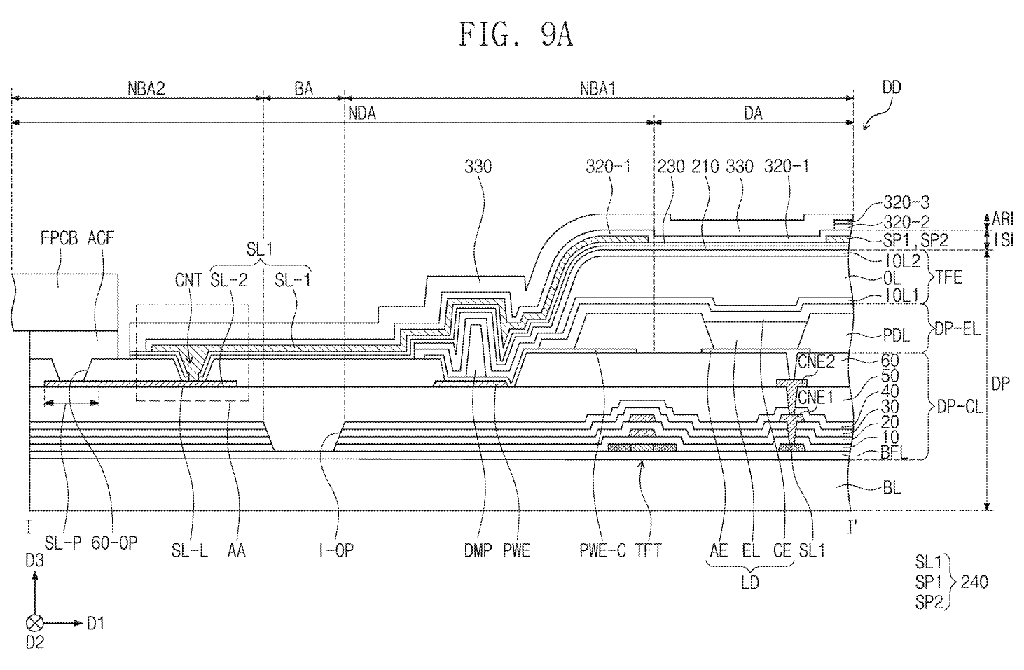

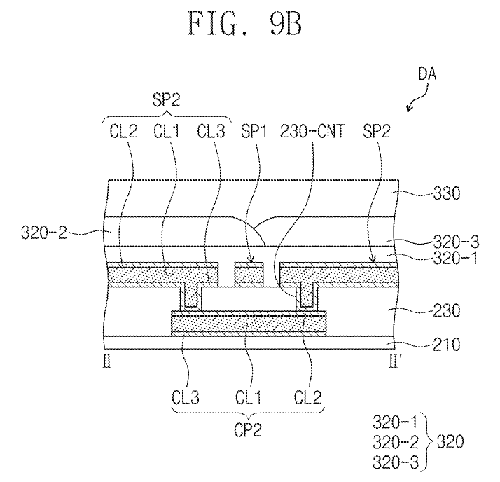

FIG. 9A is a cross-sectional view of the display device DD taken along line I-I' of FIG. 7A according to another embodiment in an unbent status. FIGS. 9B and 8C are cross-sectional views of the display device DD taken along line II-II' of FIG. 7A. Hereinafter, description of a configuration identical to the configuration in FIGS. 8A to 8D are referred to the description made with reference to FIGS. 8A to 8D.

Referring to FIGS. 9A and 9B, the black matrix 310 (see FIG. 8) is not disposed between the color filter 320 and the second insulating layer 230. As illustrated in FIG. 9A, the color filter 320 may cover the upper signal line SL-1. The color filter 320 disposed in the non-display region NDA corresponds to the reflectance- reducing pattern. As illustrated in FIG. 9B, the color filter 320 may cover the first sensing portion SP1 and the sensing patterns SP2.

The black matrix 310 may be omitted or the stacked location of the black matrix may be changed. Although not illustrated in FIGS. 9A and 9B, the black matrix 310 may be disposed between the color filter 320 and the overcoat layer 330.

For example, the color filter 320 may include a first color filter 320-1, a second color filter 320-2, and a third color filter 320-3. The first color filter 320-1 may have one among blue color, red color, and green color, and the second color filter 320-2 may have another one among the blue color, the red color, and the green color, and the third color filter 320-3 may have the other one among the blue color, the red color, and the green color. Among the three types of color filters, one color filter formed first may simultaneously cover the upper signal line SL-1, the first sensing portion SP1, and the sensing patterns SP2 and may be in contact with the first sensing portion SP1 and the sensing patterns SP2.

According to the description above, a defect of a signal line of an input sensor may be prevented. A short circuit defect between adjacent signal lines may be prevented.

In the above, description has been made with reference to embodiments of the invention, but those skilled or of ordinary skill in the art may understand that various modifications and changes may be made to the invention insofar as such modifications and changes do not depart from the spirit and technical scope of the invention set forth in the claims to be described later.

Therefore, the technical scope of the invention is not to be limited to the contents stated in the detailed description of the specification, but should be determined by the claims.

What is claimed is:

1. A display device comprising:
a base layer including a display region and a non-display region adjacent to the display region;
a lower signal line disposed in the non-display region;
a base insulating layer covering the lower signal line and overlapping the display region and the non-display region;
a light-emitting element disposed on the base insulating layer and overlapping the display region;
a thin-film encapsulation layer disposed on the base insulating layer and sealing the light-emitting element;
at least one inorganic layer disposed on the thin-film encapsulation layer and overlapping the display region and the non-display region;
a sensing electrode disposed on the at least one inorganic layer and overlapping the display region;
an upper signal line overlapping the non-display region and connecting the lower signal line and the sensing electrode;
a reflectance-reducing pattern disposed on the at least one inorganic layer and including a dye or a pigment; and
an overcoat layer disposed on the at least one inorganic layer and overlapping the reflectance-reducing pattern,
wherein the lower signal line and the upper signal line are connected through at least one contact hole penetrating a corresponding layer among the at least one inorganic layer and the base insulating layer, and
the upper signal line is covered by the reflectance-reducing pattern.

2. The display device of claim 1, wherein the base insulating layer comprises an organic layer,
the base insulating layer covers a side surface of a pad portion of the lower signal line, and
an opening exposing an upper surface of the pad portion of the lower signal line is defined in the base insulating layer.

3. The display device of claim 2, wherein the thin-film encapsulation layer, the at least one inorganic layer, and the overcoat layer do not overlap the pad portion.

4. The display device of claim 3, wherein the overcoat layer covers the reflectance-reducing pattern, and an end of the overcoat layer is closer to the pad portion of the lower signal line than an end of the reflectance-reducing pattern.

5. The display device of claim 1, wherein the upper signal line comprises a first conductive layer, a second conductive layer disposed on the first conductive layer, and a third conductive layer disposed on the second conductive layer.

6. The display device of claim 5, wherein the reflectance-reducing pattern covers side surfaces of the first conductive layer, the second conductive layer, and the third conductive layer.

7. The display device of claim 1, wherein the at least one contact hole comprises a first contact hole penetrating the base insulating layer and a second contact hole penetrating the at least one inorganic layer.

8. The display device of claim 7, wherein the at least one inorganic layer is disposed inside the first contact hole, and the second contact hole is disposed inside the first contact hole.

9. The display device of claim 1, wherein the at least inorganic layer comprises a first inorganic layer and a second inorganic layer disposed on the first inorganic layer,
the sensing electrode comprises a first sensing electrode and a second sensing electrode that are insulated from and intersected with each other in a plan view,
the first sensing electrode has an integral shape,
the second sensing electrode comprises a sensing pattern disposed at a same layer as the first sensing electrode and a bridge pattern disposed at a layer different from a layer at which the sensing pattern is disposed, and
the bridge pattern is disposed between the first inorganic layer and the second inorganic layer and connected to the sensing pattern through a contact hole penetrating the second inorganic layer.

10. The display device of claim 1, wherein the reflectance-reducing pattern comprises a black matrix including a black pigment or a black dye, and
the black matrix is in contact with the upper signal line and an upper surface of the at least one inorganic layer.

11. The display device of claim 10, wherein the reflectance-reducing pattern is disposed on the at least one inorganic layer and further comprises a color filter overlapping the light-emitting element, and the color filter is disposed on them black matrix.

12. The display device of claim 1, further comprising a first color filter, a second color filter, and a third color filter, which are disposed on the at least one inorganic layer and have different colors from each other,
wherein the light-emitting element includes a first color light-emitting element disposed under the first color filter, a second color light-emitting element disposed under the second color filter, and a third color light-emitting element disposed under the third color filter, and the reflectance-reducing pattern includes a same material as any one among the first color filter, the second color filter, and the third color filter.

13. The display device of claim 12, wherein one among the first color filter, the second color filter, and the third color filter is in contact with the sensing electrode, and the reflectance-reducing pattern comprises a same material as the color filter in contact with the sensing electrode.

14. The display device of claim 1, wherein the reflectance-reducing pattern overlaps the sensing electrode, and the upper signal line has a same stacked structure as the sensing electrode.

15. An electronic device comprising:
a display device including a display region and a non-display region adjacent to the display region; and
a circuit board electrically connected to the display device,
wherein the display device includes:
a lower signal line disposed on the non-display region;
a base insulating layer covering the lower signal line and overlapping the display region and the non-display region;
a light-emitting element disposed on the base insulating layer and overlapping the display region;
a thin-film encapsulation layer disposed on the base insulating layer and sealing the light-emitting element;
at least one inorganic layer disposed on the thin-film encapsulation layer and overlapping the display region and the non-display region;
a sensing electrode disposed on the at least one inorganic layer and overlapping the display region;
an upper signal line overlapping the non-display region and connecting the lower signal line and the sensing electrode;
a reflectance-reducing pattern disposed on the at least one inorganic layer and including a dye or a pigment; and
an overcoat layer disposed on the at least one inorganic layer and overlapping the reflectance-reducing pattern,
wherein the lower signal line and the upper signal line being connected through at least one contact hole penetrating a corresponding layer among the at least one inorganic layer and the base insulating layer, and
the upper signal line being covered by the reflectance-reducing pattern.

16. The electronic device of claim 15, further comprising an anisotropic conductive adhesive layer,
wherein the circuit board includes a substrate signal line,
the substrate signal line and the lower signal line are electrically connected through the anisotropic conductive adhesive layer,
the base insulating layer includes an organic layer,
an opening exposing an upper surface of a pad portion of the lower signal line is defined in the base insulating layer, and
the base insulating layer and the pad portion of the lower signal line are in contact with the anisotropic conductive adhesive layer.

17. The electronic device of claim 15, wherein the electronic device does not comprise a polarizing film disposed inside or outside the display device.

18. The electronic device of claim 15, wherein the upper signal line comprises a first conductive layer, a second conductive layer disposed on the first conductive layer, and a third conductive layer disposed on the second conductive layer, and
the reflectance-reducing pattern covers side surfaces of the first conductive layer, the second conductive layer, and the third conductive layer.

19. The electronic device of claim 15, wherein the at least one contact hole comprises:
a first contact hole penetrating the base insulating layer; and
a second contact hole penetrating the at least one inorganic layer,
wherein the at least one inorganic layer is disposed inside the first contact hole, and the second contact hole is disposed inside the first contact hole.

20. The electronic device of claim 15, wherein the reflectance-reducing pattern comprises a black matrix including a black pigment or a black dye, and the black matrix in contact with the upper signal line and an upper surface of the at least one inorganic layer.
